(19) United States
(12) Patent Application Publication
(10) Pub. No.: US 2018/0323158 A1
(43) Pub. Date: Nov. 8, 2018

(54) MAGNETIC INDUCTOR STACK INCLUDING INSULATING MATERIAL HAVING MULTIPLE THICKNESSES

(71) Applicant: International Business Machines Corporation, Armonk, NY (US)

(72) Inventors: Hariklia Deligianni, Alpine, NJ (US); Bruce B. Doris, Slingerlands, NJ (US); Eugene J. O'Sullivan, Nyack, NY (US); Naigang Wang, Ossining, NY (US)

(21) Appl. No.: 15/584,766

(22) Filed: May 2, 2017

(51) Int. Cl. H01L 23/64; H01L 23/522; H01F 17/00

(52) U.S. Cl. CPC H01L 23/645; H01F 17/0013; H01L 23/522; H01L 23/5227

(57) ABSTRACT

Provided is an inductor structure. In embodiments of the invention, the inductor structure includes a laminated first stack and a laminated second stack. The laminated first stack includes one or more layers of a magnetic material and one or more layers of a first insulating material having a thickness. The inductor structure also includes at least one layer of a second insulating material having a thickness. The thickness of the at least one layer of the second insulating material is different than the thickness of each of the layers of the first insulating material.

### BACKGROUND

The present invention relates in general to on-chip magnetic devices, and more specifically, to on-chip magnetic structures, e.g., a laminated magnetic inductor stack, including insulating materials having multiple thicknesses.

Inductors, resistors, and capacitors are the main passive elements constituting an electronic circuit. Inductors are used in circuits for a variety of purposes, such as in noise reduction, inductor-capacitor (LC) resonance calculators, and power supply circuitry. On-chip magnetic inductors are important passive elements in applications such as on-chip power converters and radio frequency (RF) integrated circuits. Inductors having magnetic core materials with thicknesses ranging several 100 nm to a few microns can be implemented to achieve a high energy density. For example, to achieve the high energy storage required for power management, on-chip inductors can require relatively thick magnetic stacks or yokes (e.g., several microns or more).

### SUMMARY

Provided is an inductor structure for use in a semiconductor device. In embodiments of the invention, the inductor structure includes a laminated first stack and a laminated second stack. The laminated first stack includes one or more layers of a magnetic material and one or more layers of a first insulating material having a thickness. The inductor structure also includes at least one layer of a second insulating material having a thickness. The thickness of the at least one layer of the second insulating material is different than the thickness of each of the layers of the first insulating material.

One or more embodiments of the invention provide an inductor structure for use in a semiconductor device. The inductor structure includes layers of magnetic material, first layers of insulating material having a first thickness, and second layers of insulating material having a second thickness. The second thickness is greater than the first thickness.

One or more embodiments of the invention provide a method of forming an inductor structure for use in an inductor structure. The method includes forming a first laminated stack. Forming the first laminated stack includes depositing one or more layers of magnetic material and depositing one or more layers of a first insulating material having a first thickness. The method further includes depositing at least layer of a second insulating material with a second thickness. The second thickness is different from the first thickness.

### BRIEF DESCRIPTION OF THE DRAWINGS

The subject matter of embodiments is particularly pointed out and distinctly defined in the claims at the conclusion of the specification. The foregoing and other features and advantages are apparent from the following detailed description taken in conjunction with the accompanying drawings in which:

FIG. 1 depicts a cross-sectional view of an inductor structure after a processing stage according to one or more embodiments of the present invention;

FIG. 2 depicts a cross-sectional view of the inductor structure after a processing stage according to one or more embodiments of the present invention;

FIG. 3 depicts a cross-sectional view of the inductor structure after a processing stage according to one or more embodiments of the present invention;

FIG. 4 depicts a cross-sectional view of the inductor structure after a processing stage according to one or more embodiments of the present invention; and

FIG. 5 depicts a cross-sectional view of the inductor structure after a processing stage according to one or more embodiments of the present invention.

### DETAILED DESCRIPTION

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted that the term “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well-known and so, in the interest of brevity, many conventional steps will only be mentioned briefly herein or will be omitted entirely without providing the well-known process details.

By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to a more detailed description of technologies that are more specifically relevant to aspects of the present invention, as previously discussed herein, inductors are used in circuits for a variety of purposes, such as in noise reduction, inductor-capacitor (LC) resonance calculators, and power supply circuitry. Examples of inductor integration include a transformer, which can include metal wires or lines (conductors) formed parallel to each other by silicon processing techniques directed to forming metal features. The inductor structures can be formed about the parallel metal lines to form a closed magnetic circuit and to provide a large inductance and magnetic coupling among the metal lines. The inclusion of the magnetic material and the enclosure, e.g., substantial or complete enclosure, of the metal lines can increase the magnetic coupling between the metal lines and the inductor for a given size of the inductor. The magnetic materials of an inductor can also be useful for RF and wireless circuits as well as power converters and EMI noise reduction.

Among the various types of inductors the laminated film-type inductor is widely used in applications requiring miniaturization and high current due to the reduced size and improved inductance per coil turn of these inductors relative to other inductor types. Laminated film-type inductors include laminated stacks that can be formed, for example, by depositing alternating layers of magnetic and dielectric material. Lamination of the magnetic stacks minimizes magnetic loss. One challenge associated with laminated inductors is balancing the overall thickness of the laminated stack against magnetic loss requirements. While thick magnetic layers offer faster throughput and are significantly more efficient to deposit, increasing the thickness of the laminated stack causes a corresponding increase in magnetic losses. Depositing thicker dielectric layers can help to mitigate magnetic loss, but it is time consuming to deposit each dielectric layer (also known as isolation or insulating layers) to a relatively thick film thickness.

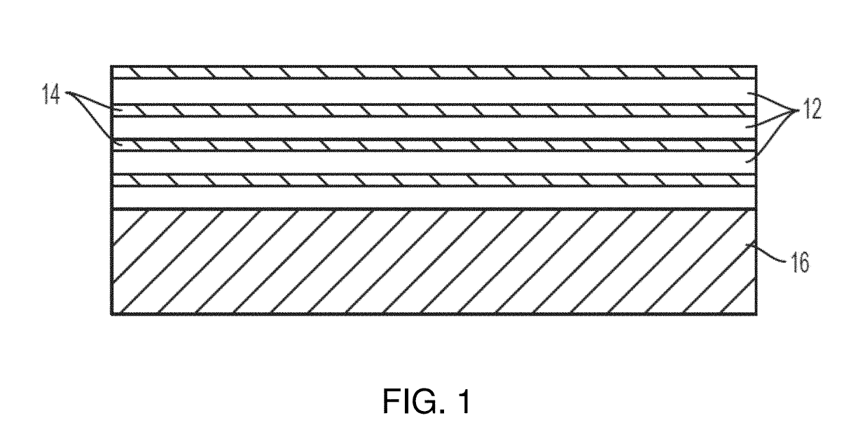

Turning now to an overview of aspects of the present invention, one or more embodiments of the invention provide methods and structures configured to reduce or prevent magnetic loss in an inductor structure. In one or more embodiments of the invention, magnetic loss can be reduced by including an insulating layer in the magnetic stack that is thicker than other insulating layers above or below the thicker insulating layer. Methods for forming an inductor structure and inductor structures in accordance with embodiments of the invention are described in detail below by referring to the accompanying drawings in FIGS. 1-5.

FIG. 1 depicts a cross-sectional view of an inductor structure after a processing stage according to one or more embodiments of the invention. As depicted in FIG. 1, a first laminated stack including magnetic material layers 12 and dielectric material layers 14 can be deposited on a wafer 16. The wafer 16 can have undergone known semiconductor front end of line processing (FEOL), middle of the line processing (MOL), and back end of the line processing (BEOL). FEOL processes can include, for example, wafer preparation, isolation, well formation, gate patterning, spacer, extension and source/drain implantation, and silicide formation. The MOL can include, for example, gate contact formation, which can be an increasingly challenging part of the whole fabrication flow, particularly for lithography patterning. In the BEOL, interconnects can be fabricated with, for example, a dual damascene process using PECVD deposited interlayer dielectric (ILDs), PVD metal barriers, and electrochemically plated conductive wire materials. The wafer 16 can include a bulk silicon substrate or a silicon on insulator (SOI) wafer. The wafer 16 can be made of any suitable material, such as, for example, Ge, SiGe, GaAs, InP, AlGaAs, or InGaAs.

The first laminated stack including magnetic material layers 12 and dielectric material layers 14 can include a plurality of alternating magnetic material layers 12 and dielectric material layers 14. For example, the first laminated stack including magnetic material layers 12 and dielectric material layers 14 can include four magnetic material layers 12 alternating with four dielectric material layers 14. For ease of discussion, reference is made to a first laminated stack including four magnetic material layers 12 alternating with four dielectric material layers 14. It is understood, however, that the first laminated stack can include any number of magnetic material layers 12 alternating with a corresponding number of dielectric material layers 14. For example, the first laminated stack can include two magnetic material layers, five magnetic material layers, eight magnetic material layers, or any number of magnetic material layers, along with a corresponding number of dielectric material layers.

Each of the magnetic material layers 12 in the first laminated stack can have a thickness of about 50 nm to about 200 nm, for example, about 100 nm. The magnetic material layers 12 can be deposited through vacuum deposition technologies (i.e., sputtering) or electrodepositing through an aqueous solution.

The magnetic layers 12 can be made of any suitable magnetic material known in the art, such as, for example, a ferromagnetic material, soft magnetic material, iron alloy, nickel alloy, cobalt alloy, ferrites, plated materials such as permalloy, or any suitable combination of these materials. In some embodiments of the invention, the magnetic material layers 12 includes a Co containing magnetic material, FeTaN, FeNi, FeAlO, or combinations thereof. Inductor core structures from these materials can have low eddy losses, a high magnetic permeability, and a high saturation flux density.

The dielectric material layers 14 can include dielectric materials such as, for example, silicon dioxide (SiO₂), silicon nitride (SiN), silicon oxynitride (SiOₓN_{y}), magnesium oxide (MgO), or aluminum oxide (AlO₂). The bulk resistivity and the eddy current loss of the magnetic structure can be controlled by the dielectric material layers 14. Each of the dielectric material layers 14 can isolate each of the magnetic material layers 12 from each other in the stack. The dielectric material layers 14 can be deposited using a deposition process, including, for example, PVD, CVD, PECVD, or a combination thereof.

The dielectric material layers 14 can each have a thickness of about 1 nm to about 500 nm and can each be about one half or greater of the thickness of each of the magnetic layers 12. For example, each of the dielectric material layers 14 in the first laminated stack can have a thickness of about 5 nm to about 10 nm, for example, about 10 nm.

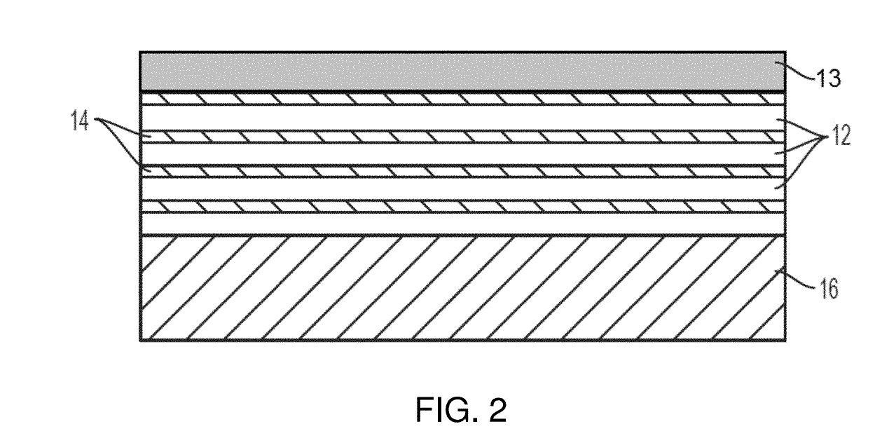

FIG. 2 depicts a cross-sectional view of the inductor structure after a processing stage according to one or more embodiments of the invention. As depicted in FIG. 2, a relatively thick insulating material layer 13 can be deposited on the first laminated stack including magnetic material layers 12 and dielectric material layers 14.

The insulating material layer 13 can include dielectric materials such as, for example, silicon dioxide (SiO₂), silicon nitride (SiN), silicon oxynitride (SiOₓN_{y}), magnesium oxide (MgO), or aluminum oxide (AlO₂). The insulating material layer 13 can have a thickness of about 50 nm to about 1 μm. In some embodiments, the thickness of insulating material layer 13 can be from about 50 nm to about 500 nm. In some embodiments, the thickness of insulating material layer 13 can be about 500 nm. The thickness of insulating material layer 13 can be greater than the thickness of dielectric material layers 14. In some embodiments, the insulating material layer 13 includes a same material as the dielectric material layers 14. In some embodiments, the insulating material layer 13 does not include a same material as the dielectric material layers 14. In some instances, the insulating material layer 13 can be a combination of the same material as the dielectric material in layers 14 and dielectric materials not the same as in dielectric layers 14.

As previously described herein, the presence of thicker insulating material layer 13 can help to prevent magnetic loss. In some embodiments of the invention, thick insulating material layer 13 can be deposited periodically in the inductor structure. The result is a reduction in the magnetic loss of the inductor while bypassing the loss in throughput associated with increasing the thickness of every dielectric layer. For example, in some embodiments of the invention, insulating material layer 13 can be deposited after a first laminated stack including four magnetic material layers 12 and four dielectric material layers 14.

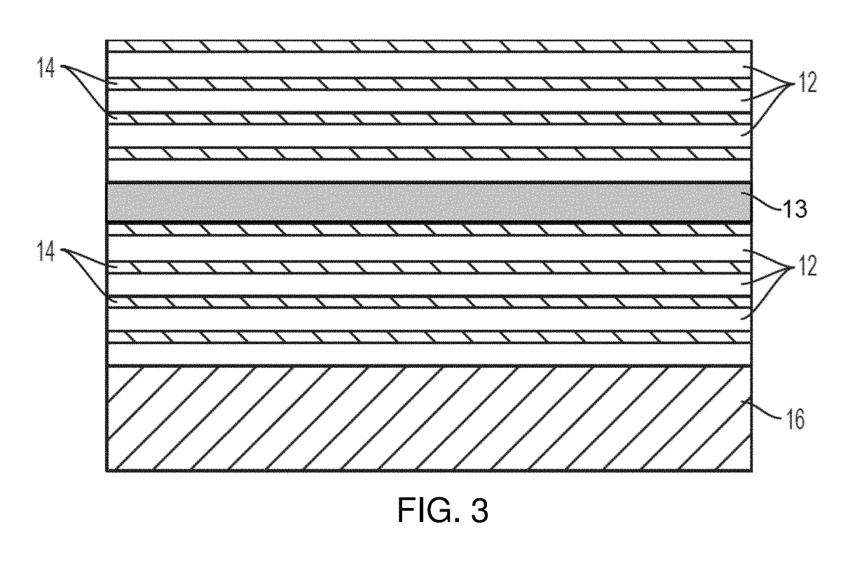

FIG. 3 depicts a cross-sectional view of the inductor structure after a processing stage according to one or more embodiments of the invention. As depicted in FIG. 3, a second laminated stack including magnetic material layers 12 and dielectric material layers 14 can be deposited on the insulating material layer 13. In some embodiments, the magnetic material layer 12 included in the second laminated stack includes a same material as the magnetic material layers 12 included in the first laminated stack. In some embodiments, the magnetic material layer 12 included in the second laminated stack does not include a same material as the magnetic material layers 12 included in the first laminated stack.

The second laminated stack including magnetic material layers 12 and dielectric material layers 14 can include a plurality of alternating magnetic material layers 12 and dielectric material layers 14. For example, the second laminated stack including magnetic material layers 12 and dielectric material layers 14 can include four magnetic material layers 12 alternating with four dielectric material layers 14.

For ease of discussion, reference is made to a second laminated stack including four magnetic material layers 12 alternating with four dielectric material layers 14. In some embodiments of the invention, the second laminated stack can include any number of magnetic material layers 12 alternating with a corresponding number of dielectric material layers 14. For example, the second laminated stack can include two magnetic material layers, five magnetic material layers, eight magnetic material layers, or any number of magnetic material layers, along with a corresponding number of dielectric material layers. The number of magnetic material layers in the second laminated stack does not need to match the number of magnetic material layers in the first laminated stack.

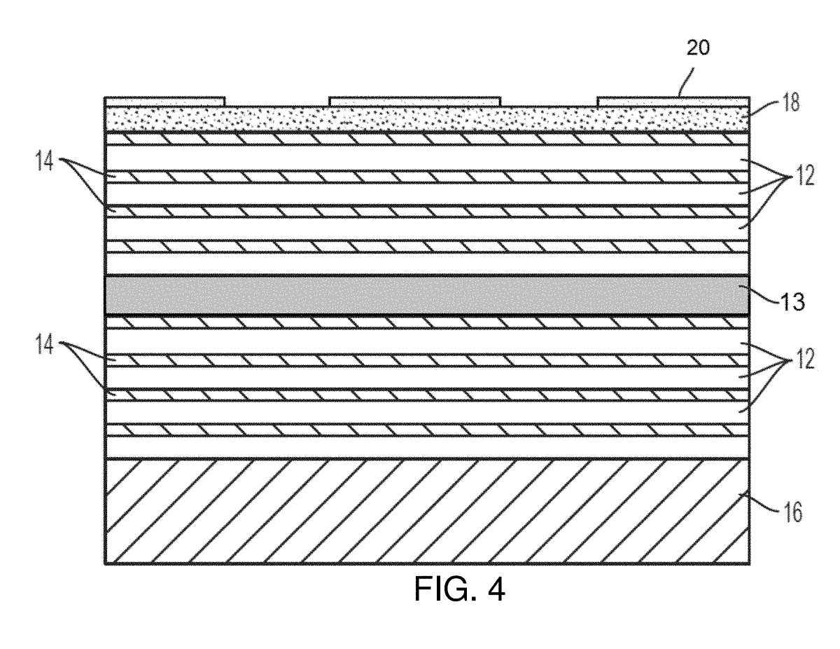

FIG. 4 depicts a cross-sectional view of the inductor structure after a processing stage according to one or more embodiments of the invention. As depicted in FIG. 4, a hard mask 18 can be deposited on the second laminated stack including magnetic material layers 12 and dielectric material layers 14. A resist image 20 can be formed, e.g., lithographically, on the hard mask 18 to provide additional structures and connections.

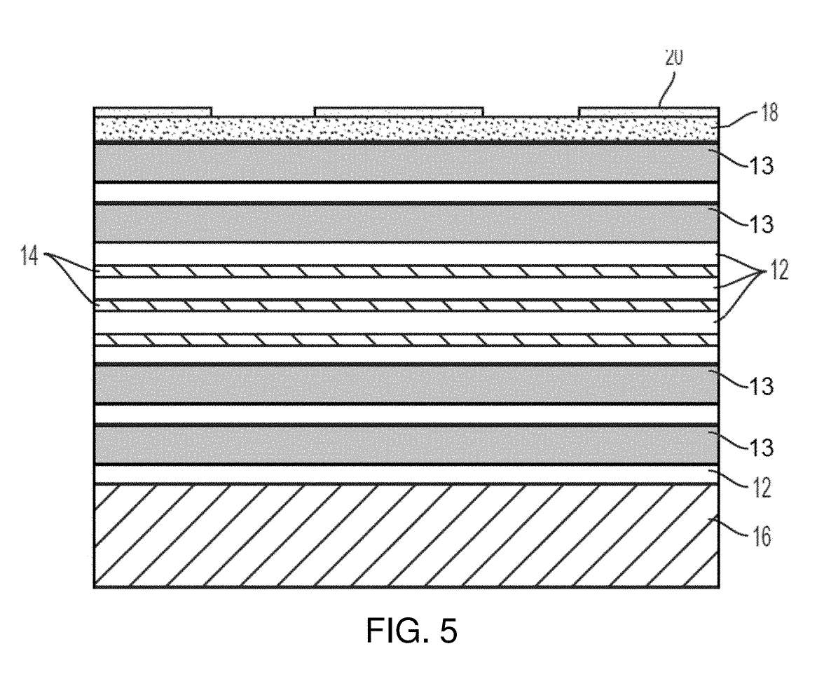

FIG. 5 depicts a cross-sectional view of an inductor structure according to one or more embodiments of the invention. In some embodiments of the invention, one or more laminated stacks with thicker insulating material layers 13 can be formed closer to the inductor coils or wire wrapped around the inductor, and one or more laminated stacks with thinner dielectric material layers 14 can be formed farther away from the coils. As depicted in FIG. 5, the relative locations of one or more laminated stacks with thicker insulating material layers 13 and one or more laminated stacks with thinner dielectric material layers 14 determine the location of magnetic material layers 12 relative to the coils or wire wrapped around the inductor.

The magnetic loss caused by eddy currents in a thick film inductor is largest in the region of the inductor where the coil is in close proximity to the magnetic material. Specifically, magnetic layers closer to the coil (that is, the “inner layers”) have larger losses than magnetic layers further from the coil (the “outer layers”). Moreover, magnetic flux densities in the space occupied by inner layers are generally higher than those characterizing the outer layers due to the magnetic reluctance of the insulating layers (also called spacer layers) interposed between the winding and the outer layers. Due to these relatively large magnetic flux densities in the space occupied by the inner layers, the inner layers tend to magnetically saturate at lower drive currents and have greater losses than the outer layers. Accordingly, the inner layer region is a critical region—the losses in this critical region dominate the overall losses of the inductor.

As magnetic film thicknesses increase, the eddy currents become severe enough to degrade the quality factor (also known as “Q”) of the inductor. The quality factor of an inductor is the ratio of its inductive reactance to its resistance at a given frequency, and is a measure of its efficiency. The maximum attainable quality factor for a given inductor across all frequencies is known as peak Q (or maximum Q). Some applications better utilize a peak Q at a low frequency and other applications better utilize a peak Q be at a high frequency.

As depicted in FIG. 5, a first laminated stack including magnetic material layers 12 and insulating material layers 13 can be deposited on wafer 16. The first laminated stack including magnetic material layers 12 and insulating material layers 13 can include a plurality of alternating magnetic material layers 12 and insulating material layers 13. For example, the first laminated stack including magnetic material layers 12 and insulating material layers 13 can include two magnetic material layers 12 alternating with two insulating material layers 13. For ease of discussion, reference is made to a first laminated stack including two magnetic material layers 12 alternating with two insulating material layers 13. In some embodiments of the invention, the first laminated stack can include any number of magnetic material layers 12 alternating with a corresponding number of insulating material layers 13. For example, the first laminated stack can include two magnetic material layers, five magnetic material layers, eight magnetic material layers, or any number of magnetic material layers, along with a corresponding number of insulating material layers.

In some embodiments, the number of magnetic material layers 12 included in the second laminated stack is the same as the number of the magnetic material layers 12 included in the first laminated stack. In some embodiments, the number of magnetic material layers 12 included in the second laminated stack is different from the number of the magnetic material layers 12 included in the first laminated stack. The second laminated stack including magnetic material layers 12 and dielectric material layers 14 can include a plurality of alternating magnetic material layers 12 and dielectric material layers 14. For example, the second laminated stack including magnetic material layers 12 and dielectric material layers 14 can include three magnetic material layers 12 alternating with three dielectric material layers 14. For ease of discussion, reference is made to a second laminated stack including three magnetic material layers 12 alternating with three dielectric material layers 14. In some embodiments of the invention, the second laminated stack can include any number of magnetic material layers 12 alternating with a corresponding number of dielectric material layers 14. For example, the second laminated stack can include two magnetic material layers, five magnetic material layers, eight magnetic material layers, or any number of magnetic material layers, along with a corresponding number of dielectric material layers. The thickness of the dielectric material layers 14 in the second laminated stack can be different from the thickness of the dielectric material layers 14 in the first laminated stack.

A third laminated stack including magnetic material layers 12 and insulating material layers 13 can be deposited on the second laminated stack including magnetic material layers 12 and dielectric material layers 14. In some embodiments, the magnetic material layers 12 included in the third laminated stack includes a same material as the magnetic material layers 12 included in the second laminated stack and/or the magnetic material layers 12 included in the first laminated stack. In some embodiments, the magnetic material layers 12 included in the third laminated stack does not include a same material as the magnetic material layers 12 included in the second laminated stack and/or the magnetic material layers 12 included in the first laminated stack.

The third laminated stack including magnetic material layers 12 and insulating material layers 13 can include a plurality of alternating magnetic material layers 12 and insulating material layers 13. For example, the third laminated stack including magnetic material layers 12 and insulating material layers 13 can include two magnetic material layers 12 alternating with two insulating material layers 13.

For ease of discussion, reference is made to a third laminated stack including two magnetic material layers 12 alternating with two insulating material layers 13. In some embodiments of the invention, the third laminated stack can include any number of magnetic material layers 12 alternating with a corresponding number of insulating material layers 13. For example, the third laminated stack can include two magnetic material layers, five magnetic material layers, eight magnetic material layers, or any number of magnetic material layers, along with a corresponding number of dielectric material layers.

A hard mask 18 can be deposited on the third laminated stack including magnetic material layers 12 and insulating material layers 13. A resist image 20 can be formed, e.g., lithographically, on the hard mask 18.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments described herein.

What is claimed is:

1. An inductor structure for use in a semiconductor device, comprising:
a laminated first stack including:
one or more layers of a magnetic material; and
one or more layers of a first insulating material having a thickness, wherein the layers of magnetic material alternate with the first layers of insulating material; and
at least one layer of a second insulating material having a thickness; wherein:
the thickness of the at least one layer of the second insulating material is different than the thickness of each of the layers of the first insulating material.

2. The inductor structure of claim 1, wherein the magnetic material includes one or more materials selected from the group comprising a Co containing magnetic material, FeTaN, and FeNi.

3. The inductor structure of claim 1, wherein the insulating material includes one or more of silicon dioxide, silicon nitride, silicon oxynitride, magnesium oxide, and aluminum oxide.

4. The inductor structure of claim 1, wherein the thickness of the at least one layer of second insulating material is greater than the thickness of each of the layers of the first insulating material.

5. The inductor structure of claim 4, further comprising a laminated second stack including:
one or more layers of the magnetic material; and
one or more layers of a third insulating material having a thickness, wherein:
the layers of magnetic material alternate with the one or more layers of the third insulating material;
the thickness of the at least one layer of the second insulating material is greater than the thickness of each of the layers of the third insulating material;
the at least one layer of the second insulating material is located between the laminated first stack and the laminated second stack.

6. The inductor structure of claim 1, wherein the thickness of each of the layers of the first insulating material is greater than the thickness of the at least one layer of the second insulating material.

7. The inductor structure of claim 6, further comprising a laminated second stack including:
one or more layers of the magnetic material; and
one or more layers of the third insulating material having a thickness; wherein:
the layers of magnetic material alternate with the layers of the third insulating material;
the thickness of each of the layers of the third insulating material is greater than the thickness of the at least one layer of the second insulating material; and
the at least one layer of the second insulating material is located between the laminated first stack and the laminated second stack.

8. The inductor structure of claim 7, further comprising a laminated third stack including the at least one layer of the second insulating material.

9. The inductor structure of claim 1, wherein the layers of first insulating material include layers having a thickness of about 50 nm to about 1 μm.

10. The inductor structure of claim 1, wherein the layers of first insulating material include layers have a thickness of about 50 nm and the at least one layer of second insulating material has a thickness of about 500 nm.

11. An inductor structure for use in a semiconductor device, comprising:
layers of magnetic material; and
a first layers of insulating material having a first thickness; and
a second layer of insulating material having a second thickness; wherein
the second thickness is greater than the first thickness.

12. The inductor structure of claim 11, wherein:
the magnetic material includes one or more materials selected from the group comprising a Co containing magnetic material, FeTaN, and FeNi; and
the insulating material includes one or more of silicon dioxide, silicon nitride, silicon oxynitride, magnesium oxide, and aluminum oxide.

13. The inductor structure of claim 11, comprising:
a laminated first stack including:
the layers of magnetic material; and
the first layers of insulating material having the first thickness, the first layers of magnetic material alternating with the first layers of insulating material.

14. A method of forming an inductor structure for use in a semiconductor device, comprising:
forming a first laminated first stack including:
depositing one or more layers of magnetic material; and
depositing one or more layers of a first insulating material having a first thickness, wherein the layers of magnetic material are deposited in an alternating manner with the layers of the first insulating material; and
depositing at least one layer of a second insulating material layer having a second thickness, the second thickness being different than the first thickness.

15. The method of claim 14, wherein:
the magnetic material includes one or more materials selected from the group comprising a Co containing magnetic material, FeTaN, and FeNi; and
the insulating material includes one or more of silicon dioxide, silicon nitride, silicon oxynitride, magnesium oxide, and aluminum oxide.

16. The method of claim 14, wherein:
the second thickness is greater than the first thickness; and
the method further comprises forming a laminated second stack, the method including:
depositing the layers of magnetic material; and
depositing layers of a third insulating material having a third thickness; wherein:
the layers including magnetic material are deposited in an alternating manner with the layers of the third insulating material;
the second thickness is greater than the third thickness; and
the at least one second insulating material layer is located between the laminated first stack and the laminated second stack.

17. The method of claim 14, wherein:
the first thickness is greater than the second thickness; and
the method further comprises forming a laminated second stack, the method including:
depositing layers of the magnetic material; and
depositing layers of a third insulating material having a third thickness, wherein:
the layers of magnetic material are deposited in an alternating manner with the layers of the third insulating material;
the third thickness is greater than the second thickness; and
the at least one layer of the second insulating material is located between the laminated first stack and the laminated second stack.

18. The method of claim 17, further comprising forming a laminated third stack including the at least layer of the second insulating material having the second thickness.

19. The method of claim 14, wherein the first thickness is between about 50 nm to about 1 μm.

20. The method of claim 14, wherein the first thickness is about 50 nm and the second thickness is about 500 nm.
